(19) United States
(12) Patent Application Publication
(10) Pub. No.: US 2003/0219660 A1
(43) Pub. Date: Nov. 27, 2003

(54) Pattern forming method

(76) Inventors: Shinichi Ito, Yokohama-shi (JP); Riichiro Takahashi, Yokohama-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/411,148

(22) Filed: Apr. 11, 2003

(30) Foreign Application Priority Data
Apr. 12, 2002 (JP) 2002-110854

(51) Int. Cl. G03F 7/20; G03F 7/40; G03B 27/68; G03B 27/42; G03B 27/32; G03B 27/52; G03B 27/58

(52) U.S. Cl. 430/30; 430/311; 430/312; 430/313; 430/394; 355/52; 355/53; 355/27; 355/72

(57) ABSTRACT

In a pattern forming method, a photoresist layer is formed on the major surface of a to-be-processed substrate, then exposed to light to form a desired latent pattern thereon, and developed into a resist pattern. An abnormality in a size or shape of the resist pattern is detected, and is corrected. Correction is performed by irradiating the resist pattern with light of a wavelength which the photoresist layer can absorb, and changing the shape of the resist pattern.

### CROSS-REFERENCE TO RELATED APPLICATIONS

This application is based upon and claims the benefit of priority from the prior Japanese Patent Application No. 2002-110854, filed Apr. 12, 2002, the entire contents of which are incorporated herein by reference.

### BACKGROUND OF THE INVENTION

1. Field of the Invention

The present invention relates to a pattern forming method used for manufacturing semiconductor devices, ULSIs, electronic circuit components, liquid crystal display elements, etc., and more particularly to a resist pattern forming method for forming, into a desired pattern, a photoresist layer on a to-be-processed substrate.

The invention also relates to a semiconductor device manufacturing method including a process for processing a to-be-processed substrate, using a resist pattern formed by the pattern forming method. The invention further relates to a pattern inspecting/correcting apparatus and pattern slimming apparatus for implementing the pattern forming method.

2. Description of the Related Art

In accordance with recent developments in microfabrication of electronic devices and integrated circuits, variations in pattern size and shape have become a problem in the etching steps of pattern fabrication.

Current semiconductor devices have a complicated structure in which a plurality of patterns, such as isolated patterns, dense patterns, patterns with a line width of a large critical dimension (CD), patterns with a line width of a small CD, etc., are contained in a single chip. Accordingly, the process tolerance of each pattern is small, therefore variations in, for example, CD between isolated patterns, ununiformity of CD in a particular area of a chip, roughness, etc. have become problematic.

In the prior art, to overcome these problems, correction is mainly performed in an exposure process for exposing a resist pattern, using optical proximity compensation (OPC). However, this technique cannot correct abnormalities in line width CD, shape, etc. caused in resist patterns by, for example, process variations. If such abnormalities as cannot be corrected exist in a substrate, they are detected by a final test, whereafter the photoresist layer is removed from the substrate, and a resist pattern is reformed. Thus, the substrate must be reworked, which inevitably increases the manufacturing cost.

On the other hand, if a resist pattern with a line width of 70 nm or less is formed by, for example, ArF lithography, a sufficient tolerance cannot be obtained. Therefore, to form such a resist pattern, the following method is employed. Firstly, a resist pattern with a CD of approx. 100 nm is formed to which the currently available apparatuses can impart a sufficient tolerance. After that, a pattern with a CD of 70 nm or less is formed by etching with etching conditions appropriately changed.

However, it is very difficult to control the amount of etching in the direction of line width, therefore a lot of problems, such as ununiformity in CD, variations in pattern shape, other defects, etc., occur. There is thus a demand for a CD slimming technique that can be easily controlled, compared to etching, and perform CD slimming with a sufficient tolerance.

As described above, in accordance with recent developments in microfabrication of electronic devices and integrated circuits, variations in pattern size or shape have become a problem. However, in the prior art, it is difficult to correct such a local pattern abnormality. Further, although a CD slimming technique capable of forming a pattern with a line width of 70 nm or less is needed, it is difficult to achieve CD slimming with a sufficient tolerance, using currently available lithography techniques.

### BRIEF SUMMARY OF THE INVENTION

According to a first aspect of the invention, there is provided a pattern forming method comprising:

forming a photoresist layer on a major surface of a to-be-processed substrate;

exposing the photoresist layer to light to form a desired latent pattern thereon;

developing the photoresist layer into a resist pattern;

detecting an abnormality in a size or shape of the resist pattern; and

irradiating the abnormality in the resist pattern, detected by the detecting, with light of a wavelength which the photoresist layer can absorb, thereby changing the shape of the resist pattern and correcting the abnormality in the resist pattern.

According to a second aspect of the invention, there is provided a pattern forming method comprising:

forming a photoresist layer on a major surface of a to-be-processed substrate;

exposing the photoresist layer to light to form a desired latent pattern thereon;

developing the photoresist layer into a resist pattern;

detecting an abnormality in a size or shape of the resist pattern using an optical apparatus, the optical apparatus applying, to the to-be-processed substrate with the resist pattern, light having a wavelength identical to or shorter than a wavelength of the light used for exposing the resist pattern; and

correcting, immediately after the detecting, the abnormality in the resist pattern detected by the detecting, using the optical apparatus.

According to a third aspect of the invention, there is provided a pattern forming method comprising:

forming a photoresist layer on a major surface of a to-be-processed substrate;

exposing the photoresist layer to light to form a desired latent pattern thereon;

developing the photoresist layer into a resist pattern;

detecting an abnormality in a size or shape of the resist pattern using an optical apparatus, the optical apparatus applying deep ultraviolet light to the to-be-processed substrate with the resist pattern; and

correcting, immediately after the detecting, the abnormality in the resist pattern detected by the detecting, using the optical apparatus.

According to a fourth aspect of the invention, there is provided a pattern forming method comprising:

forming a photoresist layer on a major surface of a to-be-processed substrate;

exposing the photoresist layer to light to form a desired latent pattern thereon;

developing the photoresist layer into a resist pattern;

detecting a to-be-slimmed region of the resist pattern using an optical apparatus, the optical apparatus applying, to the to-be-processed substrate with the resist pattern, light having a wavelength identical to or shorter than a wavelength of the light used for exposing the resist pattern; and

performing slimming processing on the detected to-be-slimmed region for slimming the resist pattern to a desired size, using the optical apparatus, immediately after the detecting.

According to a fifth aspect of the invention, there is provided a pattern forming method comprising:

forming a photoresist layer on a major surface of a to-be-processed substrate;

exposing the photoresist layer to light to form a desired latent pattern thereon;

developing the photoresist layer into a resist pattern;

detecting a to-be-slimmed region of the resist pattern using an optical apparatus, the optical apparatus applying deep ultraviolet light to the to-be-processed substrate with the resist pattern; and

performing slimming processing on the detected to-be-slimmed region for slimming the resist pattern to a desired size, using the optical apparatus, immediately after the detecting.

According to a sixth aspect of the invention, there is provided a method of manufacturing a semiconductor device comprising:

forming a photoresist layer on a major surface of a to-be-processed substrate;

exposing the photoresist layer to light to form a desired latent pattern thereon;

developing the photoresist layer into a resist pattern;

detecting an abnormality in a size or shape of the resist pattern;

irradiating the abnormality in the resist pattern, detected by the detecting, with light of a wavelength which the photoresist layer can absorb, thereby changing the shape of the resist pattern and correcting the abnormality in the resist pattern; and

etching the to-be-processed substrate using the corrected resist pattern as a mask.

According to a seventh aspect of the invention, there is provided a pattern inspection/correction apparatus comprising:

a stage which mounts thereon a to-be-processed substrate having a major surface provided with a resist pattern formed of a photoresist layer;

a moving mechanism which moves the stage at least in two horizontal directions;

an inspection mechanism which incorporates a light source using deep ultraviolet light, and irradiates the major surface of the to-be-processed substrate with the deep ultraviolet light to detect an abnormality in a size or shape of the resist pattern;

a correction mechanism which irradiates, via a predetermined mask, a to-be-corrected region of the to-be-processed substrate with the deep ultraviolet light from the light source, thereby correcting an abnormal portion of the resist pattern; and

an atmosphere control mechanism which controls an atmosphere of a space above the major surface of the to-be-processed substrate, by supplying, to the space during inspection by the inspection mechanism, a gas which inactivates chemical reaction of the photoresist layer, and supplying, to the space during correction by the correction mechanism, a gas which activates chemical reaction of the photoresist layer.

According to an eighth aspect of the invention, there is provided a pattern slimming apparatus comprising:

a stage which mounts thereon a to-be-processed substrate having a major surface provided with a resist pattern formed of a photoresist layer;

a moving mechanism which moves the stage at least in two horizontal directions;

a slimmed-region detection mechanism which incorporates a light source using deep ultraviolet light, and irradiates the major surface of the to-be-processed substrate with the deep ultraviolet light to detect a to-be-slimmed region of the resist pattern;

a slimming mechanism which irradiates the to-be-slimmed region, detected by the slimmed-region detection mechanism, with the deep ultraviolet light from the light source, thereby slimming the resist pattern; and

an atmosphere control mechanism which controls an atmosphere of a space above the major surface of the to-be-processed substrate, by supplying, to the space during detection by the slimmed-region detection mechanism, a gas which inactivates chemical reaction of the photoresist layer, and supplying, to the space during slimming by the slimming mechanism, a gas which activates chemical reaction of the photoresist layer.

### BRIEF DESCRIPTION OF THE SEVERAL VIEWS OF THE DRAWING

FIG. 1 is a flowchart useful in explaining a pattern forming method according to a first embodiment of the invention;

FIG. 2 is a flowchart useful in explaining a general pattern forming method;

FIG. 3 is a schematic block diagram illustrating an example of an optical measuring instrument employed in the first embodiment;

FIG. 4 is a sectional view illustrating an example of a structure of an atmosphere control section in the optical measuring instrument;

FIGS. 5A-5C are plan views schematically illustrating examples of the atmosphere control section in the optical measuring instrument;

FIGS. 6A-6C are plan views schematically illustrating various resist pattern errors;

FIG. 7 is a graph illustrating the relationship between DUV irradiation time and the amount of CD slimming; and

FIG. 8 is a flowchart useful in explaining a pattern forming method according to a second embodiment.

### DETAILED DESCRIPTION OF THE INVENTION

Embodiments of the invention will be described in detail with reference to the accompanying drawings.

(First Embodiment)

In a first embodiment, pattern size control is performed by applying deep ultraviolet rays (DUV) to portions of a desired resist pattern provided on a desired portion of a to-be-processed substrate.

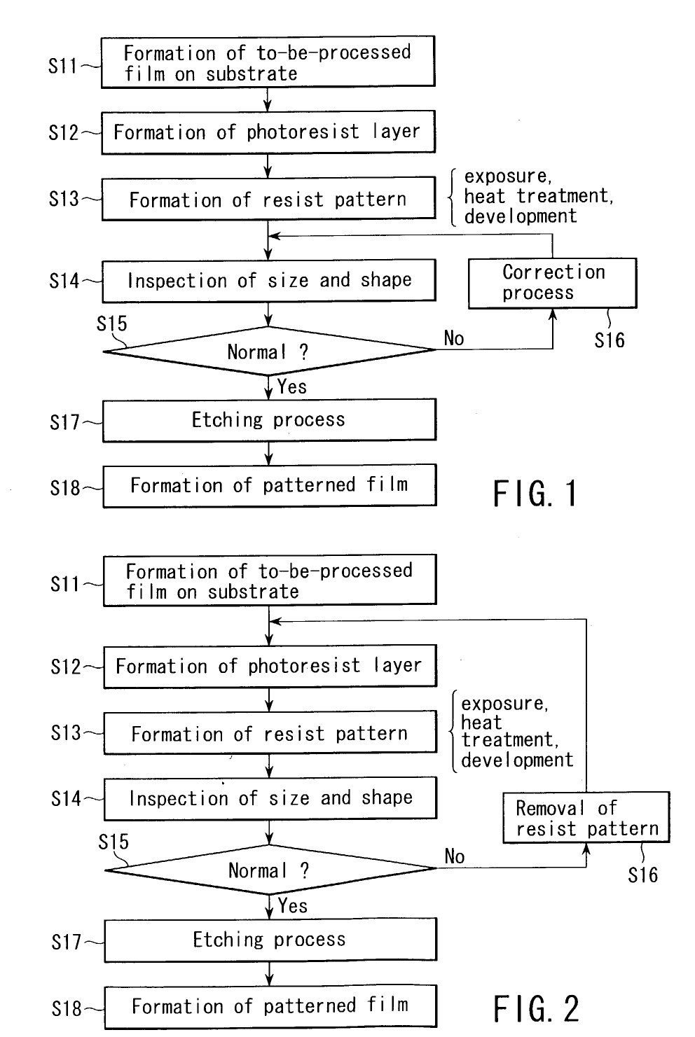

FIG. 1 is a flowchart useful in explaining a pattern forming method according to the first embodiment. Further, FIG. 2 is a flowchart illustrating a general pattern forming method as a comparative method.

Firstly, in the embodiment, as shown in FIG. 1, a to-be-processed substrate with a to-be-processed film thereon is prepared (step S11). Subsequently, the to-be-processed substrate is coated with a photoresist layer of a photosensitive resin (step S12). This photoresist layer is exposed to light to form a desired latent pattern thereon, and is then subjected to a heat treatment and development process, thereby forming a resist pattern (step S13).

After that, the size and shape of the resist pattern are measured by an optical measuring instrument using DUV as a probe (step S14). During the measurement, an inactive gas, such as nitrogen gas, is applied to the resist surface to make the resist chemically inactive.

Thereafter, the measurement result is judged (step S15). If any abnormality is found, a correction process is performed (step S16). Specifically, DUV light is again applied to the area in which abnormality is found concerning size and/or shape. During the application of DUV, an active gas, such as oxygen, is continuously supplied to the resist surface to accelerate chemical reaction of the resist. After the correction step finishes, the process is returned to the step S14, where the measurement is again performed.

In the prior art, if any abnormality is found, the resist pattern on the to-be-processed substrate is removed as shown in FIG. 2 (step S26). After that, the process is returned to the steps S12 and S13, where a so-called rework process is executed, i.e., a photoresist layer is again formed and patterned. Thus, the present embodiment differs from the prior art in that in the former, correction is performed almost simultaneously with the detection of size and shape, instead of the reworking after the step S14.

Thereafter, selected portions of the to-be-processed film are etched using the corrected resist pattern as a mask (step S17). As a result, the to-be-processed film is patterned (step S18).

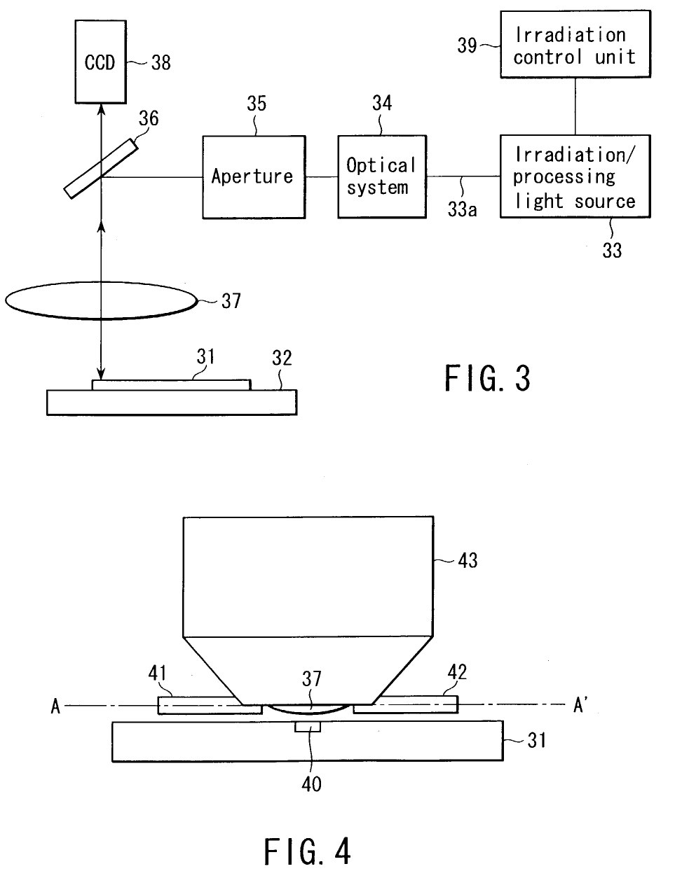

FIG. 3 shows an example of an optical measuring instrument employed in the embodiment. In FIG. 3, reference numeral 31 denotes a to-be-processed substrate, reference numeral 32 a sample stage horizontally and vertically movable, reference numeral 33 a DUV-irradiation/working light source, reference numeral 34 an optical system, reference numeral 35 an aperture, reference numeral 36 a half mirror, reference numeral 37 an objective, reference numeral 38 a CCD camera, and reference numeral 39 an irradiation control unit.

The DUV-irradiation/working light source 33 is a probe light source provided for, for example, a microscope. Observation light 33a emitted from the DUV-irradiation/working light source 33 passes through the optical system 34 and aperture 35 and reflects from the half mirror 36. The light reflected from the half mirror 36 converges on an observation point on the to-be-processed substrate 31. The image formed at the observation point is guided through the objective 37 and half mirror 36 to the light-receiving surface of the CCD camera 38.

During the observation by the CCD camera 38, in order to suppress chemical reaction of the photoresist layer, the atmosphere control mechanism shown in FIG. 4 is used to fill the space between the objective 37 and an observation point (measurement/correction position) 40 with an inactive gas, such as nitrogen. Ar, Ne, Kr, He or Xe may be used, instead of nitrogen, as the inactive gas for making the photoresist layer chemically inactive.

The atmosphere control mechanism comprises a gas introduction section 41 and exhaust section 42. The gas introduction section 41 and exhaust section 42 horizontally oppose each other, with the objective 37 interposed therebetween, the objective 37 being located close to the measurement/correction position 40 on the to-be-processed substrate 31. Further, when executing correction, the atmosphere control mechanism comprising the introduction section 41 and exhaust section 42 is used to fill the space between the objective 37 and observation point 40 with an active gas such as oxygen. In FIG. 4, reference numeral 43 denotes an objective cylinder that holds the objective 37.

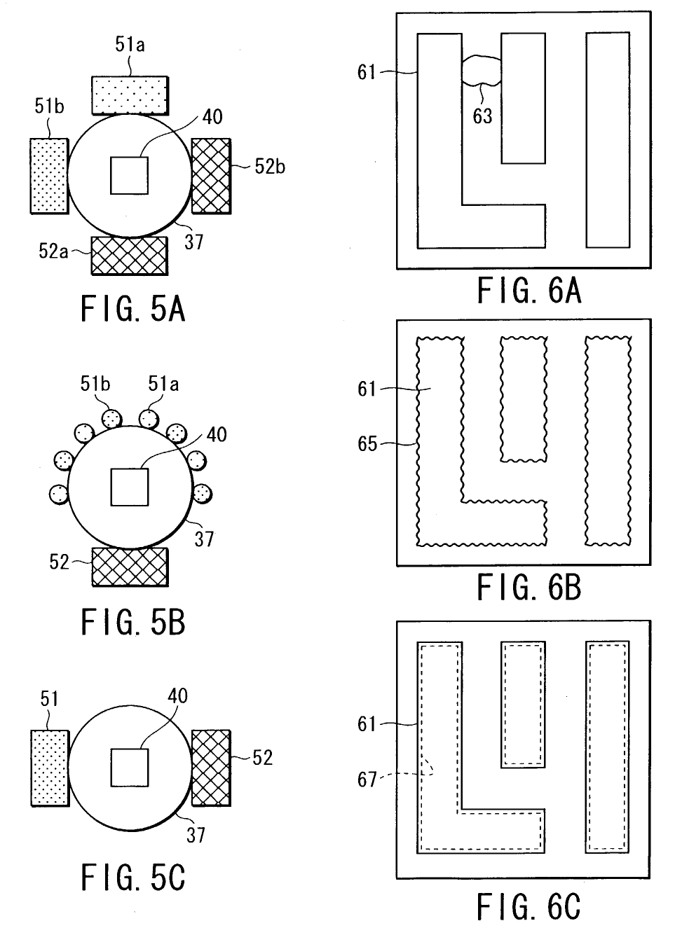

FIGS. 5A-5C show examples of the atmosphere control mechanism. These figures are sectional views corresponding to that taken along line A-A′ of FIG. 4.

The atmosphere control mechanism shown in FIG. 5A comprises inactive-gas introduction/exhaust sections and active-gas introduction/exhaust sections. The inactive-gas introduction/exhaust sections are formed of inactive-gas introduction/exhaust sections 51a and 52a opposing each other with a lens 43 interposed therebetween. Similarly, the active-gas introduction/exhaust sections are formed of active-gas introduction/exhaust sections 51b and 52b opposing each other with the lens 43 interposed therebetween. The gas introduction sections 51a and 51b each have a plurality of nozzles.

To introduce an inactive gas through the inactive gas introduction section 51a, the exhaust section 52a is operated to exhaust the air in the space between the objective 37 and observation point 40. Similarly, to introduce an active gas through the active gas introduction section 51b, the exhaust section 52b is operated to exhaust the air in the space. Thus, the introduction of a gas by operating the exhaust section opposing the gas introduction section enables prompt gas exchange at the portion (observation point) of the to-be-processed substrate closest to the lens.

The atmosphere control mechanism shown in FIG. 5B comprises a single exhaust section 52 and a plurality of inactive-gas introduction sections 51a and active-gas introduction section 51b. The inactive-gas introduction sections 51a and active-gas introduction section 51b are alternately arranged. The atmosphere control mechanism shown in FIG. 5C comprises an inactive-gas and active-gas introduction section 51 and exhaust section 52 opposing each other. In the atmosphere control mechanism of FIG. 5C, while the exhaust section 52 is operated, the valves of the gas. introduction section 51 are switched from one to another to switch the to-be-introduced gas. Both the mechanisms shown in FIGS. 5B and 5C can perform prompt gas exchange at the portion (observation point) of the to-be-processed substrate closest to the lens.

A description will now be given of pattern forming that was actually performed by the inventors of the present invention.

Firstly, an oxide film as a to-be-processed film was formed on a silicon substrate, then an anti-reflection film and chemically amplified resist film were formed thereon. Subsequently, a desired pattern was projected onto the resist film using a KrF excimer laser and exposure reticle. After that, the substrate was thermally treated and the resist film was developed, thereby forming, on the substrate, a resist pattern (for forming a gate) of a 130-nm-rule line-and-space (L/S) shape. The line width, shape, etc. of the resist pattern formed on the substrate were measured by an optical size-measuring instrument using DUV light as a probe.

In this embodiment, a microscope using DUV light of 266 nm as a probe was employed as the size-measuring instrument. The energy of the probe light of the microscope was approx. 3 μW. During the measurement, the area of the substrate to which the probe light was applied, and the resist film surface around this area were maintained in an atmosphere of nitrogen. Specifically, using the mechanism shown in FIG. 5A, while the exhaust section 52a was being operated, nitrogen gas was introduced through the inactive gas introduction section 51a. As a result of the measurement, the area, in which lines were thicker than a designed dimension, the area having a greater roughness than expected, bridging defects due to attachment of, for example, particles were found. These areas of the resist pattern were modified by switching the atmosphere of nitrogen to that of oxygen in the space between the observation point and objective. More specifically, the atmosphere of nitrogen is switched to that of oxygen in the following manner:

1) The probe light applied to the observation area of the substrate is interrupted by, for example, closing the shutter or turning off the power supply for the probe light.

2) The nitrogen supply nozzles are closed, and the oxygen supply nozzles are opened.

3) When the space has been filled with oxygen, the probe light is again applied to the observation area of the substrate by, for example, opening the shutter or turning on the power supply for the probe light.

FIGS. 6A-6C illustrate examples of measurement results. FIG. 6A schematically shows the area of a resist pattern 61 in which a bridging defect 63 due to, for example, attachment of particles, was detected between adjacent lines. FIG. 6B schematically shows the area of the resist pattern 61 that had edges 65 of a great roughness. FIG. 6C schematically shows the area of the resist pattern 61 that had a greater line width than the designed one indicated by reference numeral 67.

In the embodiment, DUV light was applied for approx. one to thirty seconds in an atmosphere of oxygen. The period of DUV irradiation was determined during irradiation while changes in the line width, the degree of roughness, the size of a defect, etc. in the pattern were observed via microscope. As a result, bridging defects due to particles were completely removed. Further, the thicker lines were slimmed to substantially the same dimension as designed.

When a defect such as line breakage has occurred, acetylene or ethylene gas is introduced instead of oxygen gas. The defective portion can be repaired (corrected) by adjusting the focal point to the defective portion, in order to cause polymerization of the resist and introduced gas at the defective portion.

To perform such a correction, the shape of the aperture 35 in the instrument of FIG. 3 is modified in accordance with the shape of a to-be-corrected portion. For example, if the irradiation optical system 34 uses a Nipkow disk with a number of holes, it irradiates only a to-be-processed portion, using a process position aperture for applying light only to such a to-be-processed portion, and the Nipkow disk. In this process, since DUV light is applied to the to-be-processed portion located at the focal position, a high light intensity can be obtained only at the focal position.

In the portions other than the to-be-processed portion, the intensity of light applied thereto attenuates to a degree at which no optical reaction occurs. Accordingly, the possibility of the portions other than the to-be-processed portion being irradiated with DUV light is very low. In other words, the possibility of pattern degradation is very low. During observation, the process-position aperture is completely opened, thereby enabling the total field of view to be used for observation. Thus, in such a confocal optical system, a high light intensity is obtained only at the focused portion. Owing to this, if the to-be-processed substrate is moved in a direction perpendicular to the optical axis, the thickness-directional correction of the resist can also be performed easily.

In the case where a laser beam is scanned within the observation field of view, the laser beam is applied when a to-be-corrected portion has reached the observation field of view, or the laser beam is applied only to the to-be-corrected portion, using the above-mentioned process-position aperture.

The period of DUV light irradiation in an atmosphere of oxygen is not limited to the above-mentioned one. Although in the embodiment, DUV irradiation is performed in an atmosphere with an oxygen concentration of 20%, it was found by experiment that substantially half the period is required in an atmosphere with oxygen concentration of 40%, while substantially twice the period is required in the atmosphere with an oxygen concentration of 10%. If the concentration of oxygen is high, the etching rate is high, therefore it is difficult to control etching. However, this is suitable for correcting a large defective portion (if it is not necessary to stop the process highly accurately). On the other hand, if the concentration of oxygen is low, the etching rate is low, which is suitable for correcting a small defective portion (if it is necessary to stop the process highly accurately). A similar tendency was obtained also when ozone gas was used. Thus, the concentration of a gas can be changed according to the type, size, etc. of a to-be-corrected portion. Further, the period required for this process depends upon the concentration of a gas, as mentioned above.

Also, in the embodiment, the irradiation power of DUV light is 3 μW. However, it was found from the experiments that substantially half the period is required if the irradiation power is 6μW, while substantially twice the period is required if the irradiation power is 1.5 μW. If the irradiation power is high, the etching rate is high, therefore it is difficult to control etching. However, this is suitable for correcting a big defective portion (if it is not necessary to stop the process highly accurately). On the other hand, if the irradiation power is low, the etching rate is low, which is suitable for correcting a small defective portion (if it is necessary to stop the process highly accurately). In those cases, DUV light with a wavelength of 266 nm was used. However, a similar tendency was obtained when other wavelengths were employed. Thus, the irradiation power can be changed according to the type, size, etc. of a to-be-corrected portion. Further, the period required for this process depends upon the irradiation power, as mentioned above.

It is preferable that nitrogen and oxygen gases are introduced through supply nozzles (incorporated in an introduction section) while suction nozzles (incorporated in an exhaust section) are operated to suck the gases, as is shown in FIGS. 5A and 5C. This structure enables prompt exchange of atmosphere gases.

Although the embodiment uses nitrogen as an inactive gas during observation, He, Ne, Ar, Kr, etc. may be used instead. Even when observation was performed using any of He, Ne, Ar and Kr and DUV light with a wavelength of 350 nm or less that is not absorbed by He, Ne, Ar and Kr, it could be performed successfully without damaging the pattern. Further, oxygen gas used for correction is not necessarily 100% oxygen. Even oxygen in the same concentration as the atmosphere (approx. 20%) could sufficiently correct defective portions. Also, the same advantage could be obtained even when a gas containing ozone as an oxidation component was used.

In addition, although the embodiment employs light of 266 nm, DUV light is not limited to this. From the experiments concerning the correction using various light sources and the photoresist layer, it was found that satisfactory correction can be performed if light of 350 nm or less that can be absorbed by the photoresist layer is used. However, it is desirable, for measurement of a pattern, to use light of a wavelength identical to or shorter than the wavelength used to expose the pattern.

After the to-be-processed substrate was thus prepared, it was etched by reactive ion etching (RIE) under standard etching conditions, using a resist pattern as a mask. Even after the RIE process, short-circuiting due to a bridge defect was not found. Furthermore, since line width correction was performed in the resist-forming process, the resultant gates could have an accurate line width, whereby a highly reliable device could be produced.

In the embodiment, a photosensitive resin is used as the material of a photoresist layer. However, the same advantage can be obtained also when photosensitive polyimide is used as an insulation layer. It was found by experiment that DUV light irradiation in an atmosphere of an inactive gas enabled a pattern to be inspected without being damaged. Further, removal of defects, slimming of a polyimide pattern, etc. could be performed by correction in an atmosphere of a gas containing an element that reacts with photosensitive polyimide.

The size correction and CD slimming employed in the embodiment will now be described in detail.

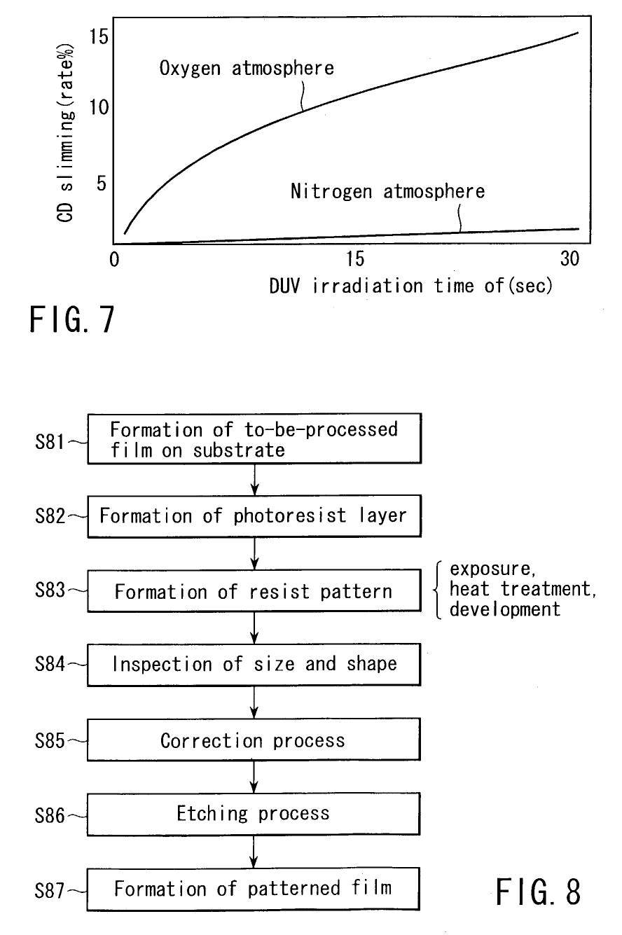

The size or shape measurement is performed in an atmosphere of nitrogen, which suppresses the chemical change in the surface of the resist film caused by DUV irradiation, thereby preventing the resist film from being damaged. During actual observation using DUV light in an atmosphere of nitrogen, the resist film was not damaged. Even in the pattern obtained after RIE, damage, such as defective processing, was not found. In the experiments, the change in CD was 1% or less thirty seconds after DUV light was applied to the resist pattern in an atmosphere of nitrogen, as shown in FIG. 7. After the RIE process, the change in CD was approx. 0.7% thirty seconds after DUV irradiation was started. This value is within the average variation range in all processes.

If an abnormality is detected as a result of size measurement, i.e., if the measured value is higher than the allowable maximum value, correction is performed at once by switching the to-be-applied gas from nitrogen to oxygen with DUV light kept applied. By continuously supplying oxygen to the area irradiated with DUV light, chemical reaction, in the area, of the resist or an underlayer, such as an anti-reflection film, is accelerated, thereby changing the etching ratio during RIE. In light of this, the pattern size after RIE can be controlled by appropriately selecting the intensity and irradiation period of DUV light in an atmosphere of oxygen. In the experiments, the degree of CD slimming of the resist pattern after thirty-minute irradiation of DUV light in an atmosphere of oxygen was approx. 15% as shown in FIG. 7. Further, the CD slimming degree of the pattern obtained after RIE that was executed using the resultant resist pattern as a mask was approx. 3%.

It is not always necessary to perform CD slimming on the entire major surface of a to-be-processed substrate. Further, CD slimming may be performed in units of blocks, chips or to-be-processed substrates. To slim only a particular block of the device by substantially 20% after RIE, the portions other than the block are masked so that only the block will be irradiated, and 45-second irradiation is performed in an atmosphere of an active gas. This may be done to slim, for example, a logic section in a system on a chip.

Further, a method for uniformly slimming the pattern line width in units of chips is employed to realize, for example, a pattern line width close to the resolution limit of an exposure unit. Furthermore, there is a case where the pattern line width is gradually slimmed on a chip, specifically, where the line width varies on a chip due to ununiform development, or where the line width varies on a chip during RIE due to differences in circuit density.

In these cases, if the line width varies over the entire chip, it is advisable to perform slimming while performing irradiation correction corresponding to the amount of variation. Specifically, an aperture in the form of a slit is provided at an irradiation source, an image obtained through the aperture is projected onto a chip, and the movement speed of a to-be-processed substrate is varied in accordance with the line width of a resist. The greater the resist line width, the slower the movement of the substrate. Alternatively, the amount of irradiation is varied in accordance with the resist line width such that the greater the resist line width, the greater the amount of irradiation. In any case, the greater the line width of the remaining pattern, the higher the irradiation energy is set.

A description will now be given of a method for correcting the roughness of a pattern shown in FIG. 6B.

Assume that the roughness value of a resist pattern that is higher than the allowable maximum value is obtained as a result of measurement of the resist pattern in an atmosphere of nitrogen. In this case, the gas to be applied is switched from nitrogen to a gas containing oxygen, and DUV light is set to an appropriate intensity and is irradiated for an appropriate period of time, thereby accelerating chemical reaction of a resist or an underlayer, such as an anti-reflection film, and reducing the roughness of the pattern after RIE.

In the experiment performed by the inventors of the present invention, DUV light was irradiated for approx. five seconds for shape correction. As a result, after RIE, the CD of the pattern was reduced by 3%, and the degree of roughness of the pattern was reduced by approx. 20%.

A method for correcting the defective portion as shown in FIG. 6A that is caused by attachment of an organic substance will be described.

A defect detection apparatus using DUV light applies DUV light to a detected organic attachment or bridging portion between pattern components, while oxygen is blown thereto. As a result, the organic attachment can be decomposed and eliminated. At the same time, the pattern is observed using a monitor to confirm whether the defective portions have been appropriately corrected, and DUV irradiation is stopped. Thus, defect detection and correction can be performed simultaneously. This remarkably reduces wiring short-circuiting after RIE. In the experiment by the inventors of the present invention, no wiring short-circuiting defects were detected, which is a remarkable improvement compared to a conventional case where five to ten wiring short-circuiting defects were detected.

As described above, in the embodiment, a substrate with a resist pattern provided thereon is inspected by a DUV optical measuring instrument, and the portions of the substrate, at which abnormalities in size or shape and/or other defects have been found, are irradiated with DUV light in an atmosphere of oxygen. Thus, size, shape and defects after RIE are controlled. Furthermore, CD slimming can be easily performed after RIE by simultaneously applying DUV light to particular regions after forming a resist pattern and photosensitive polyimide pattern. As a result, cost reduction due to reduction of reworking, a remarkable increase in yield, high integration of ICs without using a next-generation exposure apparatus, etc. can be realized.

(Second Embodiment)

In a second embodiment, simultaneous correction of the entire surface of a substrate will be described.

In the first embodiment, a description has been given of the case where local size, shape and/or defect correction of a chip is performed using DUV light, while the substrate is observed and measured. However, in the cases described below, for example, the entire surface of a to-be-processed substrate, or a particular bulk region (the entire chip or a particular block on a chip) needs to be simultaneously irradiated with DUV light.

(1) If, for example, a resist pattern having a CD of 70 nm or less is formed, the currently available lithography techniques cannot provide a sufficient tolerance. Therefore, a resist pattern with a CD of approx. 100 nm is formed to which the currently available lithography techniques can impart a sufficient tolerance. After that, the pattern size is slimmed to a desired value by simultaneously irradiating the entire surface of the substrate with DUV light in an atmosphere of oxygen.

(2) Further, if the size difference between the surfaces of substrates of a certain lot falls outside an allowable range although each substrate surface has a uniform CD, the entire surface of each substrate is irradiated with DUV light to correct the size difference between the substrates. These processes can be performed also in consideration of size variations after RIE.

Specifically, as shown in the flowchart of FIG. 8, firstly, a to-be-processed substrate with a to-be-processed film formed thereon is prepared (step S81). Subsequently, a photoresist layer is formed on the to-be-processed film (step S82). Thereafter, the photoresist layer is exposed to light to form a desired latent pattern thereon, and subjected to heat and development treatments. As a result, a resist pattern is formed (step S83). The CD of this resist pattern is set to, for example, 100 nm at which the resist pattern can be formed with a sufficient tolerance even by the currently available lithography techniques.

Subsequently, the size and shape of the resist pattern are measured by an optical measuring instrument using DUV light as a probe (step S84). If the entire surface of the substrate is subjected to CD slimming as described in the above item (1), atmosphere control is performed so that oxygen can be applied to the resist surface at any time instead of an inactive gas such as nitrogen. As a result, CD slimming is performed (step S85). By this CD slimming, the CD of the resist pattern can be reduced to, for example, 70 nm. It is desirable that a lamp light source capable of simultaneously irradiating a wider region be used as a DUV light source, instead of a probe light source incorporated in a microscope.

After that, the to-be-processed film is etched using, as a mask, the resist pattern obtained after CD slimming (step S86), as in the first embodiment. As a result, a fine film pattern can be formed with a higher accuracy than the conventional methods (step S87).

As described above, in the second embodiment, CD slimming is performed by irradiating a resist pattern with DUV light, as in the first embodiment. In this embodiment, however, lamp light is used to uniformly apply light to the entire major surface of a substrate or a particular bulk region of the substrate. Accordingly, the entire pattern on the substrate can be corrected to a desired CD finer than the minimum value that can be reached by the currently available lithography techniques.

In the experiments by the inventors of the present invention, approx. 15% CD slimming could be achieved by thirty-second irradiation, as in the first embodiment. The irradiation energy was approx. 1-3 J/cm². For 30% CD slimming, approx. one-minute DUV irradiation was needed. However, the energy is not limited to the value since it depends upon the amount of CD slimming, the type of resist, etc.

(Modification)

The invention is not limited to the above-described embodiments. In the first embodiment, a probe light source incorporated in a microscope is used as a light source for applying light to a to-be-processed substrate. Further, in the second embodiment, a lamp light source is used as the light source. However, the light source is not limited to these. It is sufficient if light is applied uniformly. For uniform light application, it is desirable that the intensity uniform portion of light irradiated by a light source is extracted through an aperture or slit, and is applied to a to-be-processed substrate by, for example, scanning.

Further, it is desirable that the intensity profile of light applied to a to-be-slimmed region be adjusted so that the photosensitive resin pattern size in the region will be a desired one. Furthermore, when a to-be-slimmed region is scanned with light in the form of a slit, it is desirable that the light intensity profile in the slit or the scanning speed be adjusted so that the photosensitive resin pattern size in the region will be a desired one. Also, the to-be-slimmed region is selected, according to need, from the entire surface of a substrate, a pattern region on the substrate, a chip region, a particular region in a chip, etc.

In addition, in the first embodiment, monochrome light of 266 nm is used, while in the second embodiment, light of a broader wavelength range, including light of 266 nm, is used. However, the light is not limited to light of 266 nm, monochrome light or white light. It is sufficient if the light does not significantly damage a resist when, for example, it is absorbed in the resist, and can provide the same advantage as that obtained by the above-described embodiments. Yet further, a to-be-processed film is not necessarily provided on the to-be-processed substrate. The substrate may be directly irradiated with light. In this case, since a resist pattern is directly provided on the substrate, the substrate itself is etched using the resist pattern as a mask.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
forming a photoresist layer on a major surface of a to-be-processed substrate;
exposing the photoresist layer to light to form a desired latent pattern thereon;
developing the photoresist layer into a resist pattern;
detecting an abnormality in a size or shape of the resist pattern; and
irradiating the abnormality in the resist pattern, detected by the detecting, with light of a wavelength which the photoresist layer can absorb, thereby changing the shape of the resist pattern and correcting the abnormality in the resist pattern.

2. A pattern forming method comprising:
forming a photoresist layer on a major surface of a to-be-processed substrate;
exposing the photoresist layer to light to form a desired latent pattern thereon;
developing the photoresist layer into a resist pattern;
detecting an abnormality in a size or shape of the resist pattern using an optical apparatus, the optical apparatus applying, to the to-be-processed substrate with the resist pattern, light having a wavelength identical to or shorter than a wavelength of the light used for exposing the resist pattern; and
correcting, immediately after the detecting, the abnormality in the resist pattern detected by the detecting, using the optical apparatus.

3. The method according to claim 2, wherein a gas which inactivates chemical reaction of the photoresist layer is supplied to an inspection region of the resist pattern when the abnormality in the size or shape of the resist pattern is detected.

4. The method according to claim 3, wherein the gas which inactivates chemical reaction of the photoresist layer is selected from the group consisting of nitrogen, argon, neon, krypton, helium and xenon.

5. The method according to claim 2, wherein a gas containing an element which activates chemical reaction of the photoresist layer is supplied to an inspection region of the resist pattern when the abnormality in the size or shape of the resist pattern is corrected.

6. The method according to claim 5, wherein the gas containing the element which activates chemical reaction of the photoresist layer is selected from the group consisting of oxygen and a hydrocarbon compound gas.

7. The method according to claim 5, wherein one of concentration of the element contained in the gas for activating chemical reaction of the photoresist layer, a process time and light irradiation energy is adjusted to set an amount of correction for the resist pattern.

8. The method according to claim 2, wherein the detecting is performed while a gas which inactivates chemical reaction of the photoresist layer is supplied, and the gas which inactivates chemical reaction is switched to a gas containing an element which activates chemical reaction of the photoresist layer immediately after the abnormality in the size or shape of the resist pattern is detected, thereby correcting the detected abnormality.

9. A pattern forming method comprising:
forming a photoresist layer on a major surface of a to-be-processed substrate;
exposing the photoresist layer to light to form a desired latent pattern thereon;
developing the photoresist layer into a resist pattern;
detecting an abnormality in a size or shape of the resist pattern using an optical apparatus, the optical apparatus applying deep ultraviolet light to the to-be-processed substrate with the resist pattern; and
correcting, immediately after the detecting, the abnormality in the resist pattern detected by the detecting, using the optical apparatus.

10. The method according to claim 9, wherein a gas which inactivates chemical reaction of the photoresist layer is supplied to an inspection region of the resist pattern when the abnormality in the size or shape of the resist pattern is detected.

11. The method according to claim 10, wherein the gas which inactivates chemical reaction of the photoresist layer is selected from the group consisting of nitrogen, argon, neon, krypton, helium and xenon.

12. The method according to claim 9, wherein a gas containing an element which activates chemical reaction of the photoresist layer is supplied to an inspection region of the resist pattern when the abnormality in the size or shape of the resist pattern is corrected.

13. The method according to claim 12, wherein the gas containing the element which activates chemical reaction of the photoresist layer is selected from the group consisting of oxygen and a hydrocarbon compound gas.

14. The method according to claim 12, wherein one of concentration of the element contained in the gas for activating chemical reaction of the photoresist layer, a process time and light irradiation energy is adjusted to set an amount of correction for the resist pattern.

15. The method according to claim 9, wherein the detecting is performed while a gas which inactivates chemical reaction of the photoresist layer is supplied, and the gas which inactivates chemical reaction is switched to a gas containing an element which activates chemical reaction of the photoresist layer immediately after the abnormality in the size or shape of the resist pattern is detected, thereby correcting the detected abnormality.

16. A pattern forming method comprising:
forming a photoresist layer on a major surface of a to-be-processed substrate;
exposing the photoresist layer to light to form a desired latent pattern thereon;
developing the photoresist layer into a resist pattern;
detecting a to-be-slimmed region of the resist pattern using an optical apparatus, the optical apparatus applying, to the to-be-processed substrate with the resist pattern, light having a wavelength identical to or shorter than a wavelength of the light used for exposing the resist pattern; and
performing slimming processing on the detected to-be-slimmed region for slimming the resist pattern to a desired size, using the optical apparatus, immediately after the detecting.

17. The method according to claim 16, wherein the to-be-slimmed region is one of the entire major surface of the to-be-processed substrate, a pattern region of the major surface of the to-be-processed substrate, a chip region on the major surface of the to-be-processed substrate, and a particular region in the chip region.

18. The method according to claim 16, wherein a gas which inactivates chemical reaction of the photoresist layer is supplied to the to-be-slimmed region of the resist pattern when the to-be-slimmed region is detected.

19. The method according to claim 18, wherein the gas which inactivates chemical reaction of the photoresist layer is selected from the group consisting of nitrogen, argon, neon, krypton, helium and xenon.

20. The method according to claim 16, wherein a gas containing an element which activates chemical reaction of the photoresist layer is supplied to the to-be-slimmed region of the resist pattern when the to-be-slimmed region is detected.

21. The method according to claim 20, wherein the gas containing the element which activates chemical reaction of the photoresist layer is selected from the group consisting of oxygen and a hydrocarbon compound gas.

22. The method according to claim 16, wherein an intensity profile of light used to perform the slimming processing is adjusted such that the to-be-slimmed region irradiated with the light has a desired size.

23. The method according to claim 16, wherein the to-be-slimmed region is scanned with light in the form of a slit to perform the slimming processing, and an intensity profile or scanning speed of the light in the form of a slit is adjusted such that the to-be-slimmed region scanned with the light has a desired size.

24. A pattern forming method comprising:
forming a photoresist layer on a major surface of a to-be-processed substrate;
exposing the photoresist layer to light to form a desired latent pattern thereon;
developing the photoresist layer into a resist pattern;
detecting a to-be-slimmed region of the resist pattern using an optical apparatus, the optical apparatus applying deep ultraviolet light to the to-be-processed substrate with the resist pattern; and
performing slimming processing on the detected to-be-slimmed region for slimming the resist pattern to a desired size, using the optical apparatus, immediately after the detecting.

25. The method according to claim 24, wherein the to-be-slimmed region is one of the entire major surface of the to-be-processed substrate, a pattern region of the major surface of the to-be-processed substrate, a chip region on the major surface of the to-be-processed substrate, and a particular region in the chip region.

26. The method according to claim 24, wherein a gas which inactivates chemical reaction of the photoresist layer is supplied to the to-be-slimmed region of the resist pattern when the to-be-slimmed region is detected.

27. The method according to claim 26, wherein the gas which inactivates chemical reaction of the photoresist layer is selected from the group consisting of nitrogen, argon, neon, krypton, helium and xenon.

28. The method according to claim 24, wherein a gas containing an element which activates chemical reaction of the photoresist layer is supplied to the to-be-slimmed region of the resist pattern when the to-be-slimmed region is detected.

29. The method according to claim 28, wherein the gas containing the element which activates chemical reaction of the photoresist layer is selected from the group consisting of oxygen and a hydrocarbon compound gas.

30. The method according to claim 24, wherein an intensity profile of light used to perform the slimming processing is adjusted such that the to-be-slimmed region irradiated with the light has a desired size.

31. The method according to claim 24, wherein the to-be-slimmed region is scanned with light in the form of a slit to perform the slimming processing, and an intensity profile or scanning speed of the light in the form of a slit is adjusted such that the to-be-slimmed region scanned with the light has a desired size.

32. A method of manufacturing a semiconductor device comprising:
forming a photoresist layer on a major surface of a to-be-processed substrate;
exposing the photoresist layer to light to form a desired latent pattern thereon;
developing the photoresist layer into a resist pattern;
detecting an abnormality in a size or shape of the resist pattern;
irradiating the abnormality in the resist pattern, detected by the detecting, with light of a wavelength which the photoresist layer can absorb, thereby changing the shape of the resist pattern and correcting the abnormality in the resist pattern; and
etching the to-be-processed substrate using the corrected resist pattern as a mask.

33. A pattern inspection/correction apparatus comprising:
a stage which mounts thereon a to-be-processed substrate having a major surface provided with a resist pattern formed of a photoresist layer;
a moving mechanism which moves the stage at least in two horizontal directions;
an inspection mechanism which incorporates a light source using deep ultraviolet light, and irradiates the major surface of the to-be-processed substrate with the deep ultraviolet light to detect an abnormality in a size or shape of the resist pattern;
a correction mechanism which irradiates, via a predetermined mask, a to-be-corrected region of the to-be-processed substrate with the deep ultraviolet light from the light source, thereby correcting an abnormal portion of the resist pattern; and
an atmosphere control mechanism which controls an atmosphere of a space above the major surface of the to-be-processed substrate, by supplying, to the space during inspection by the inspection mechanism, a gas which inactivates chemical reaction of the photoresist layer, and supplying, to the space during correction by the correction mechanism, a gas which activates chemical reaction of the photoresist layer.

34. The apparatus according to claim 33, wherein the atmosphere control mechanism includes a gas switch mechanism which switches the gases supplied to the space above the major surface of the to-be-processed substrate, depending upon whether the inspection mechanism or correction mechanism operates,
the gas switch mechanism setting the atmosphere of the space to an inactive state by supplying, to the space, the gas which inactivates chemical reaction of the photoresist layer, before the inspection mechanism starts inspection, the gas switch mechanism setting the atmosphere of the space to an active state by supplying, to the space, the gas which activates chemical reaction of the photoresist layer, after the inspection mechanism finishes the inspection and before the correction mechanism starts correction.

35. The apparatus according to claim 33, wherein the gas switch mechanism includes a gas supply mechanism and a gas exhaust mechanism horizontally opposing each other with an objective interposed therebetween, the objective being commonly used by the inspection mechanism and the correction mechanism.

36. A pattern slimming apparatus comprising:
a stage which mounts thereon a to-be-processed substrate having a major surface provided with a resist pattern formed of a photoresist layer;
a moving mechanism which moves the stage at least in two horizontal directions;
a slimmed-region detection mechanism which incorporates a light source using deep ultraviolet light, and irradiates the major surface of the to-be-processed substrate with the deep ultraviolet light to detect a to-be-slimmed region of the resist pattern;
a slimming mechanism which irradiates the to-be-slimmed region, detected by the slimmed-region detection mechanism, with the deep ultraviolet light from the light source, thereby slimming the resist pattern; and
an atmosphere control mechanism which controls an atmosphere of a space above the major surface of the to-be-processed substrate, by supplying, to the space during detection by the slimmed-region detection mechanism, a gas which inactivates chemical reaction of the photoresist layer, and supplying, to the space during slimming by the slimming mechanism, a gas which activates chemical reaction of the photoresist layer.

37. The apparatus according to claim 36, wherein the atmosphere control mechanism includes a gas switch mechanism which switches the gases supplied to the space above the major surface of the to-be-processed substrate, depending upon whether the slimmed-region detection mechanism or slimming mechanism operates,
the gas switch mechanism setting the atmosphere of the space to an inactive state by supplying, to the space, the gas which inactivates chemical reaction of the photoresist layer, before the slimmed-region detection mechanism starts detection, the gas switch mechanism setting the atmosphere of the space to an active state by supplying, to the space, the gas which activates chemical reaction of the photoresist layer, after the slimmed-region detection mechanism finishes detection and before the slimming mechanism starts slimming.

38. The apparatus according to claim 36, wherein the gas switch mechanism includes a gas supply mechanism and a gas exhaust mechanism horizontally opposing each other with an objective interposed therebetween, the objective being commonly used by the slimmed-region detection mechanism and the slimming mechanism.
